(19) United States
(12) Patent Application Publication
(10) Pub. No.: US 2010/0086860 A1
(43) Pub. Date: Apr. 8, 2010

(54) PHOTOPOLYMER COMPOSITIONS FOR OPTICAL ELEMENTS AND VISUAL DISPLAYS

(75) Inventors: Thomas Roelle, Leverkusen (DE); Friedrich-Karl Bruder, Krefeld (DE); Thomas Faecke, Leverkusen (DE); Marc-Stephan Weiser, Leverkusen (DE); Dennis Hoenel, Zuelpich (DE); Nicolas Stoeckel, Koeln (DE)

Correspondence Address: CONNOLLY BOVE LODGE & HUTZ, LLP, P O BOX 2207, WILMINGTON, DE, 19899, US

(73) Assignee: Bayer MaterialScience AG, Leverkusen (DE)

(21) Appl. No.: 12/569,184

(22) Filed: Sep. 29, 2009

(30) Foreign Application Priority Data
Oct. 1, 2008 (EP) 08017275.2

(51) Int. Cl. G03F 7/00; C08L 75/04; C08F 2/46; C07F 9/09

(52) U.S. Cl. 430/2; 525/421; 522/97; 558/190

(57) ABSTRACT

The invention relates to novel photopolymers based on specific urethane acrylates as writing monomers, which are suitable for producing holographic media, in particular for visual display of images.

### RELATED APPLICATIONS

This application claims benefit to European Patent Application No. 08017275.2, filed Oct. 1, 2008, which is incorporated herein by reference in its entirety for all useful purposes.

### BACKGROUND OF THE INVENTION

The invention relates to novel photopolymers based on specific urethane acrylates as writing monomers which are suitable for the production of holographic media, in particular for visual display of images.

Photopolymers are materials which can be exposed by means of the superposition of two coherent light sources, a three-dimensional structure forming in the photopolymers, which structure can in general be written by a regional change of the refractive index in the material. Such structures are referred to as holograms. They can also be described as diffractive optical elements. Which optical functions such a hologram performs depends on the specific exposure.

For the use of photopolymers as a support of holograms for optical applications in the visible range, colourless or only very slightly coloured materials having a high diffraction effect are as a rule required after the exposure. Since the beginning of holography, silver halide films, in particular those having a high resolution, have been used for this purpose. Dichromate gelatin (DCG), dichromate salt-containing gelatin films or mixed forms of silver halide and DCG are also used. Both materials require a chemical aftertreatment for the formation of a hologram, which gives rise to additional costs for industrial processes and necessitates the handling of chemical developer solutions. Moreover, wet chemical processes result in swelling and subsequently shrinkage of the film, which can lead to colour shifts in the holograms, which is undesirable.

U.S. Pat. No. 4,959,284 (Dupont) describes photopolymers which consist, inter alia, of a thermoplastic, such as polyvinyl acetate, cellulose acetobutyrate or polymethyl methacrylate-styrene copolymers, which are soluble in organic solvents, a photoinitiator and at least one vinylcyclopropane derivative. In addition, EP352774A1 (Dupont) describes other monomers containing vinyl groups, such as N-vinylpyrrolidone, phenoxyethyl acrylate and acrylates of triols, such as trimethylolpropane (TMPTA) and ethoxylated trimethylolpropane (TMPEOTA), or other acrylates or acrylamides. It is known in industry that such photopolymers give useable holograms only after a prolonged thermal treatment. In their review article, O'Neill et al. (Applied Optics, Vol. 41, No. 5, page 845 ff., 2002) discuss not only the abovementioned materials but also photopolymers which are obtainable from thermoplastics and acrylamide. In addition to the unfavourable toxicological profile of acrylamide, such products do not give holograms having a high refractive index contrast.

Also known are holographically active materials into which dyes are incorporated which change their photosensitivity under the influence of light (Luo et al, Optics Express, Vol. 13, No. 8, 2005, page 3123). Similarly, Bieringer (Springer Series in Optical Sciences (2000), 76, pages 209-228) describes so-called photoaddressable polymers which are likewise polymer-bound dyes which can isomerize under the influence of light. It is possible to incorporate holograms into both classes of substances, and these materials can be used for holographic data storage. However, these products are of course strongly coloured and therefore not suitable for the applications described above.

More recently, photopolymers which are not obtained from thermoplastics but from crosslinked polymers were described: thus US 020070077498 (Fuji) describes 2,4,6-tribromophenyl acrylate which is dissolved in a polyurethane matrix. U.S. Pat. No. 6,103,454 (InPhase) likewise describes a polyurethane matrix with polymerizable components, such as 4-chlorophenyl acrylate, 4-bromostryrene and vinylnaphthalene. These formulations were developed for holographic data storage, a holographic application in which many, but also very weak, holograms readable only with electronic detectors are written and read. For optical applications in the total visible range, such formulations are not suitable.

The non-prior-published PCT application PCT/EP2008/002464 discloses formulations of urethane acrylates as writing monomers in polyurethane matrices. Both the writing monomers and the quantity ranges thereof and the possible fields of use are described in a unspecific broad manner.

Starting from PCT/EP2008/002464, it has now been found that very useful colourless holograms having a high diffraction efficiency can be obtained for optical and security applications in particular when specific unsaturated urethanes are used as writing monomers and the proportion thereof in relation to the total formulation comprising matrix components and writing monomers is at least 10% by weight.

### EMBODIMENTS OF THE INVENTION

An embodiment of the present invention is a polyurethane composition comprising a writing monomer component a) containing at least 10% by weight, based on the total weight of said polyurethane composition, of one or more unsaturated urethanes a) of formulae (I), (II), and (III) as writing monomers and polymeric compounds or corresponding matrix precursors as a matrix for the writing monomers

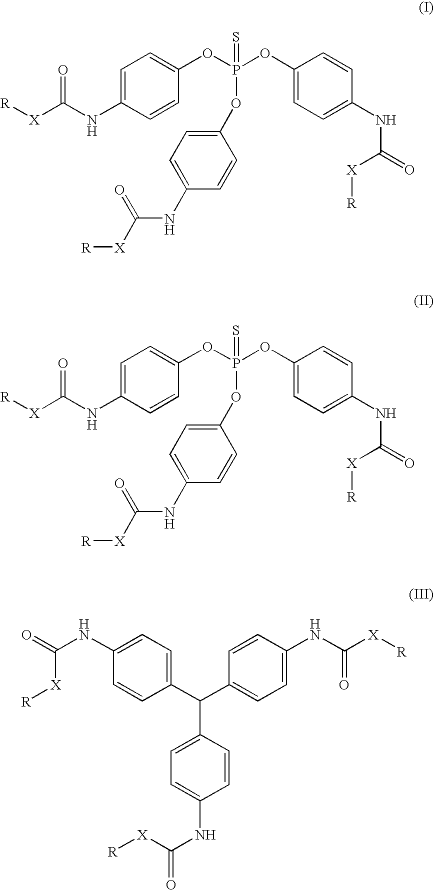

wherein
R is in each case, independently of one another, a radiation-curable group; and
X is in each case, independently of one another, a single bond between R and C═O or a linear, branched, or cyclic hydrocarbon radical which optionally contains heteroatoms and/or is optionally substituted by functional groups.

Another embodiment of the present invention is the above polyurethane composition, wherein R is a vinyl ether, acrylate, or methacrylate group.

Another embodiment of the present invention is the above polyurethane composition, wherein X is in each case a linear or branched oxyalkylene or polyoxyalkylene group.

Another embodiment of the present invention is the above polyurethane composition, wherein said one or more unsaturated urethanes a) are present in an amount of from 20 to 50% by weight, based on the total weight of said polyurethane composition.

Another embodiment of the present invention is the above polyurethane composition, wherein said corresponding matrix precursors comprise
an isocyanate component b);
an isocyanate-reactive component c); and
one or more photoinitiators d).

Yet another embodiment of the present invention is a process for producing media suitable for recording visual holograms comprising (1) applying the above polyurethane composition to a substrate or in a mould and (2) curing said polyurethane composition.

Yet another embodiment of the present invention is a process for producing media suitable for recording visual holograms comprising (1) providing a mixture of the components of the above polyurethane composition, (2) applying said polyurethane composition to a substrate or in a mould and (3) curing said polyurethane composition, wherein component b) is admixed only finally immediately before the application in (2).

Yet another embodiment of the present invention is a medium suitable for recording visual holograms produced by the above process.

Yet another embodiment of the present invention is a method for recording holograms comprising exposing the above medium by means of a laser beam.

Yet another embodiment of the present invention is an unsaturated urethane of formula (II)

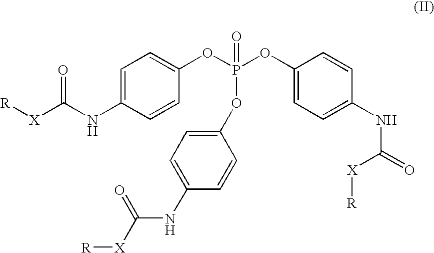

wherein
R is in each case, independently of one another, a radiation-curable group; and
X is in each case, independently of one another, a single bond between R and C═O or a linear, branched or cyclic hydrocarbon radical which optionally contains heteroatoms and/or is optionally substituted by functional groups.

### DESCRIPTION OF THE INVENTION

The present invention therefore relates to polyurethane compositions comprising a writing monomer component a), containing at least 10% by weight, based on the total composition, of one or more unsaturated urethanes a) of the formulae (I) to (III) as writing monomers and polymeric compounds or corresponding precursors as a matrix for the writing monomers, and to a process for the production of media, and to the media themselves and to a method for recording visual holograms, in which such a polyurethane composition is applied to a substrate or in a mould and is cured.

The present invention also relates to urethane acrylates of the formula (II).

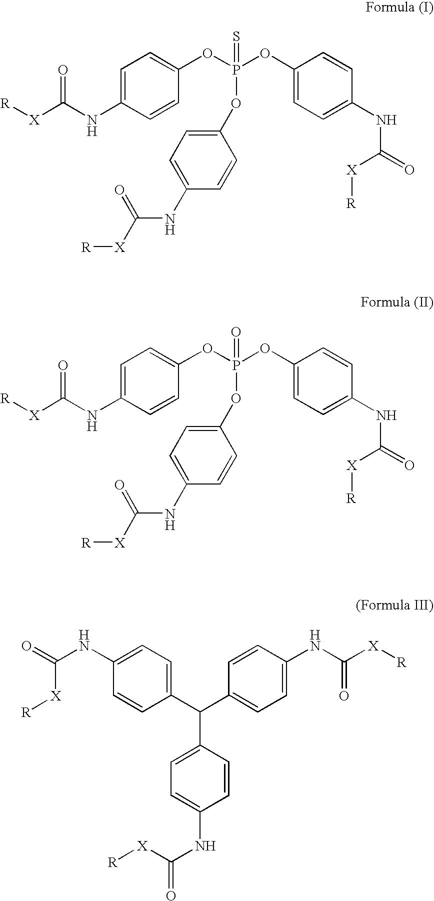

in which
R, independently of one another, is in each case a radiation-curable group and
X, independently of one another, is in each case a single bond between R and C═O or a linear, branched or cyclic hydrocarbon radical which optionally contains heteroatoms and/or is optionally substituted by functional groups.

In the context of the present invention, all functional groups which react with olefinically unsaturated compounds with polymerization under the action of actinic radiation are radiation-curable groups. These are, for example, vinyl ether (CH₂═CH—O—), maleyl (cis-HOOC—C═C—CO—O—), fumaryl (trans-HOOC—C═C—CO—O—), maleinimide, dicyclo-pentadienyl, acrylamide (CH₂═CH—(CO)—NH—), methacrylamide (CH₂═CCH₃—(CO)—NH—), acrylate (CH₂═CH—(CO)—O—) and methacrylate groups (CH₂═CCH₃—(CO)—O—).

Actinic radiation is understood as meaning electromagnetic, ionizing radiation, in particular electron beams, UV radiation and visible light (Roche Lexikon Medizin [Roche Medical Lexikon], 4th edition; Urban & Fischer Verlag, Munich 1999).

Preferably, R is a vinyl ether, acrylate or methacrylate group, particularly preferably an acrylate group.

In principle, one or more of the carbon-bound hydrogen atoms of the group R may also be replaced by C₁- to C₅-alkyl groups, which however is not preferred.

Preferably, the group X has 2 to 40 carbon atoms and one or more oxygen atoms present in the form of ether bridges. X may be either linear or branched or cyclic and substituted by functional groups. The group X is particularly preferably in each case a linear or branched oxyalkylene or polyoxyalkylene group.

Preferred polyoxyalkylene groups have up to 10, particularly preferably up to 8, repeating units of the respective oxyalkylene group.

In principle, it is possible for X to have identical or different oxyalkylene groups as repeating units, such a repeating unit preferably having 2 to 6, particularly preferably 2 to 4, carbon atoms. Particularly preferred oxyalkylene units are oxyethylene and in each case the isomeric oxypropylenes or oxybutylenes.

The repeating units within the respective group X may be present completely or partly distributed in blocks or randomly.

In a preferred embodiment of the invention, X, independently of one another, is in each case an oxyalkylene unit selected from the group consisting of —CH₂—CH₂—O—, —CH₂—CHCH₃—O—, —CHCH₃—CH₂—O—, —(CH₂—CH₂—O)ₙ—, —O(CH₂—CHCH₃—O)ₙ—, in which n is an integer from 2 to 7, and —O—CH₂—CH₂—(O—(CH₂)₅—CO)ₘ—, in which m is an integer from 1 to 5.

The unsaturated urethanes essential to the invention are obtainable, for example, by preferably stoichiometric reaction of the respective corresponding triisocyanates with the same compounds, or a mixture of different compounds, of the formula R—X—H with addition, R and X having the abovementioned meaning.

Triisocyanates used are triphenylmethane 4,4′,4″-triisocyanate, tris(p-isocyanatophenyl) thiophosphate or tris(p-isocyanatophenyl) phosphate.

For example, hydroxy-functional acrylates or methacrylates, such as 2-hydroxyethyl (meth)acrylate, polyethylene oxide mono(meth)acrylates, polypropylene oxide mono(meth)acrylates, polyalkylene oxide mono(meth)acrylates, poly(ε-caprolactone) mono(meth)acrylates, such as, for example, Tone® M100 (Dow, Schwalbach, Germany), hydroxypropyl (meth)acrylate, 4-hydroxybutyl (meth)acrylate, 3-hydroxy-2,2-di-methylpropyl (meth)acrylate, hydroxypropyl (meth)acrylate or industrial mixtures thereof are used as compounds of the formula R—X—H.

Other suitable compounds of the formula R—X—H are epoxy(meth)acrylates containing hydroxyl groups, such as the reaction products of acrylic acid and/or methacrylic acid with epoxides (glycidyl compounds). Preferred epoxy acrylates are those having a defined functionality, as can be obtained from the known reaction of acrylic acid and/or methacrylic acid and glycidyl (meth)acrylate.

In a preferred embodiment, 2-hydroxyethyl acrylate, hydroxypropyl acrylate, 4-hydroxybutyl acrylate, polyethylene oxide mono(meth)acrylate, polypropylene oxide-mono(meth)acrylate, polyalkylene oxide mono(meth)acrylate, poly(c-caprolactone) mono(meth)acrylate or industrial mixtures thereof are used as compounds of the formula R—X—H.

In a particularly preferred embodiment, 2-hydroxyethyl acrylate, hydroxypropyl acrylate, 4-hydroxybutyl acrylate or mixtures thereof are used as compounds of the formula R—X—H.

An excess of triisocyanate or R—X—H followed by a subsequent separation of compounds not converted into urethane is conceivable but, owing to the polymerization lability of the products, is not preferred.

The unsaturated urethanes essential to the invention have a content of free isocyanate groups (M=42) of less than 0.5% by weight, preferably less than 0.2% by weight, particularly preferably less than 0.1% by weight, and a content of unconverted compounds R—X—H of less 1% by weight, preferably less than 0.5% by weight and particularly preferably less than 0.2% by weight.

The urethane formation in the addition reaction can be effected with the aid of the catalysts known for accelerating isocyanate addition reactions, such as, for example, tertiary amines, tin, zinc, iron or bismuth compounds, in particular triethylamine, 1,4-diazabicyclo[2.2.2]octane, bismuth octanoate or dibutyltin dilaurate, which can be concomitantly initially introduced or subsequently metered in.

In the preparation of the unsaturated urethanes essential to the invention or subsequently stabilizers against undesired polymerization can be added. Such stabilizers may be oxygen-containing gas as well as chemical stabilizers, as described, for example, in Houben-Weyl, Methoden der organischen Chemie [Methods of Organic Chemistry], 4th Edition, Volume XIV/1, Georg Thieme Verlag, Stuttgart 1961, page 433 ff. For example, suitable stabilizers are sodium dithionite, sodium hydrogen sulphide, sulphur, hydrazine, phenylhydrazine, hydrazobenzene, N-phenyl-β-naphthylamine, N-phenylethanoldiamine, dinitrobenzene, picric acid, p-nitrosodimethylaniline, diphenylnitrosamine, phenols, such as para-methoxyphenol, 2,5-di-tert-butylhydroquinone, 2,6-di-tert-butyl-4-methylphenol, p-tert-butylpyrocatechol or 2,5-di-tert-amylhydroquinone, tetramethylthiuram disulphide, 2-mercaptobenzothiazole, dimethyldithiocarbamic acid sodium salt, phenothiazine, N-oxyl compounds, such as, for example, 2,2,6,6-tetramethylpiperidine N-oxide (TEMPO) or one of its derivatives.

Preferred stabilizers are phenothiazine, 2,6-di-tert-butyl-4-methylphenol and para-methoxyphenol and mixtures thereof.

Such stabilizers are typically used in an amount of 0.001 to 1% by weight, preferably 0.01 to 0.5% by weight, based on the unsaturated urethane to be stabilized.

If the unsaturated urethanes essential to the invention should still contain free isocyanate groups, stabilization can be effected by suitable compounds, such as acids or acid derivatives, e.g. benzoyl chloride, phthaloyl chloride, phosphinous, phosphonous and/or phosphorous acid, phosphinic, phosphoric and/or phosphoric acid and the acidic esters of the last-mentioned 6 acid types, sulphuric acid and its acidic esters and/or sulphonic acids.

The preparation of the unsaturated urethanes essential to the invention can be carried out in the presence of organic solvents which are inert to starting materials and products. Examples are coating solvents, such as ethyl acetate, butyl acetate, solvent naphtha, methoxypropyl acetate, acetone, butanone or hydrocarbons, such as cyclohexane, methylcyclohexane or isooctane.

After the reaction, the solvent can be removed from the product, for example by distillation, can remain in the product or can be exchanged for another solvent.

In a preferred embodiment, the solvent is removed by distillation after the reaction. In a further preferred embodiment, the process solvent is exchanged for another one after the reaction by distillation. For this purpose, this other solvent is added after the reaction and the process solvent is removed by distillation. A precondition for such a solvent exchange is, however, that the process solvent have a lower boiling point than the further solvent.

This further solvent is preferably a hydroxy-functional polymer (polyol). Suitable polyols of this type are di- or polyols having a number average molecular weight in the range from 500 to 13000 g/mol, preferably 700 to 8500 g/mol.

Preferred polyols for this purpose have an average hydroxyl functionality of 1.5 to 3.5, preferably of 1.8 to 3.2, particularly preferably of 1.9 to 3.1.

Such polyols of the abovementioned type are, for example, polyester alcohols based on aliphatic, cycloaliphatic and/or aromatic di-, tri- and/or polycarboxylic acids with di-, tri- and/or polyfunctional alcohols and lactone-based polyester alcohols.

Preferred polyester alcohols having a molecular weight preferably of 500 to 4000, particularly preferably 650 to 2500, g/mol are, for example, reaction products of adipic acid with hexanediol, butanediol or neopentyl glycol or mixtures of said diols.

Also suitable are polyether polyols, which are obtainable by polymerization of cyclic ethers or by reaction of alkylene oxides with an initiator molecule.

The polyethylene and/or polypropylene glycols having a number average molecular weight of 500 to 13000 g/mol, and furthermore polytetrahydrofurans having a number average molecular weight of 500 to 8000, preferably of 650 to 3000, g/mol, may be mentioned by way of example.

Also suitable are polyester-polyether-polyester block polyols, which can be obtained by reacting polyether polyols with lactones.

Also suitable are hydroxyl-terminated polycarbonates, which are obtainable by reacting dials or lactone-modified diols or bisphenols, such as, for example, bisphenol A, with phosgene or carbonic acid diesters, such as diphenyl carbonate or dimethyl carbonate.

The polymeric carbonates of 1,6-hexanediol having a number average molecular weight of 500 to 8000 g/mol and the carbonates of reaction products of 1,6-hexanediol with ε-caprolactone in a molar ratio of from 1 to 0.1 may be mentioned by way of example. Preferred carbonates are the abovementioned polycarbonate diols having a number average molecular weight of 650 to 3000 g/mol, based on 1,6-hexanediol, and/or carbonates of the reaction products of 1,6-hexanediol with ε-caprolactone in the molar ratio of from 1 to 0.33.

Hydroxyl-terminated polyamido alcohols and hydroxyl-terminated polyacrylate diols, e.g. Tegomer® BD 1000 (from Tego GmbH, Essen, Germany), can also be used.

For the abovementioned solvent exchange, polyols particularly suitable as the further solvent are polyols containing ester groups and polyether polyols of the above-mentioned type.

The preparation of the urethanes essential to the invention is effected either continuously, for example in a static mixer, or batchwise, for example in a suitable stirred vessel. In the batchwise procedure, both isocyanate and the compounds R—X—H can be initially introduced and the respective other component can be metered in at room temperature or elevated temperature. Preferably, the reaction is effected by initially introducing the isocyanate component and metering in R—X—H.

With the use of a mixture of different compounds of the formula R—X—H, these can be added either in the form of a mixture or sequentially in any sequence, it being preferable to add the compounds R—X—H in the order of increasing reactivity with the isocyanates.

The preferred reaction temperature is 40° C. to 130° C., particularly preferably 50° C. to 80° C. The temperature is adjusted by external heating and/or suitable use of the heat of reaction liberated.

The progress of the reaction of NCO and OH groups to give the urethane can be carried out spectroscopically, for example by recording infrared or near infrared spectra or by chemical analyses on samples taken.

The isocyanate content or optionally also the hydroxyl content is in particular suitable as a measure for the conversion in the reaction.

In solvent-free form, the urethanes essential to the invention typically have a double bond density, based on the radiation-curable groups, preferably acrylate and methacrylate groups, of ≧0.5, preferably ≧0.8 mol of C═C per kg of the urethane.

The polyurethane compositions according to the invention preferably have, in component a), at least 10% by weight, particularly preferably at least 15% by weight and very particularly preferably at least 20% by weight, based on the polyurethane compositions, of the unsaturated urethanes a) essential to the invention as writing monomers. However, the proportion of these writing monomers a), based on the total formulation, is preferably not more than 70% by weight, particularly preferably not more than 50% by weight.

In addition to the writing monomer component a), the polyurethane compositions according to the invention have polymeric compounds as a matrix for the writing monomers or corresponding matrix precursors from which the corresponding matrix for the writing monomers forms.

Preferably, the polyurethane compositions according to the invention contain, as synthesis components for the matrix,

an isocyanate component b)
an isocyanate-reactive component c)
and one or more photoinitiators d).

The isocyanate component b) preferably comprises polyisocyanates. Isocyanates which may be used are all compounds well known per se to the person skilled in the art or mixtures thereof, which have on average two or more NCO functions per molecule. These may have an aromatic, araliphatic, aliphatic or cycloaliphatic basis. In minor amounts, it is also possible concomitantly to use monoisocyanates and/or polyisocyanates containing unsaturated groups.

For example, butylene diisocyanate, hexamethylene diisocyanate (HDI), isophorone diisocyanate (IPDI), 1,8-diisocyanato-4-(isocyanatomethyl)octane, 2,2,4- und/or 2,4,4-trimethylhexamethylene diisocyanate, the isomeric bis(4,4′-isocyanatocyclohexyl)methane and mixtures thereof having any isomer content, isocyanatomethyl-1,8-octane diisocyanate, 1,4-cyclohexylene diisocyanate, the isomeric cyclohexanedimethylene diisocyanates, 1,4-phenylene diisocyanate, 2,4- and/or 2,6-toluene diisocyanate, 1,5-naphthylene diisocyanate, 2,4′- or 4,4′-diphenylmethane diisocyanate and/or triphenylmethane 4,4′,4″-triisocyanate are suitable.

Also possible is the use of derivatives of monomers di- or triisocyanates having urethane, urea, carbodiimide, acrylurea, isocyanurate, allophanate, biuret, oxadiazinetrione, uretdione and/or iminooxadiazinedione structures.

The use of polyisocyanates based on aliphatic and/or cycloaliphatic di- or triisocyanates is preferred.

Particularly preferably, the polyisocyanates of component b) are di- or oligomerized aliphatic and/or cycloaliphatic di- or triisocyanates.

Isocyanates, uretdiones and/or iminooxadiazinediones based on HDI, 1,8-diisocyanato-4-(isocyanatomethyl)octane or mixtures thereof are very particularly preferred.

In principle, all polyfunctional, isocyanate-reactive compounds which have on average at least 1.5 isocyanate-reactive groups per molecule can be used as component c).

Isocyanate-reactive groups in the context of the present invention are preferably hydroxyl, amino or thio groups, hydroxy compounds being particularly preferred.

Suitable polyfunctional, isocyanate-reactive compounds are, for example, polyester-, polyether-, polycarbonate-, poly(meth)acrylate- and/or polyurethane polyols.

Suitable polyester polyols are, for example, linear polyester diols or branched polyester polyols, as obtained in a known manner from aliphatic, cycloaliphatic or aromatic di- or polycarboxylic acids or their anhydrides with polyhydric alcohols having an OH functionality ≧2.

Examples of such di- or polycarboxylic acids or anhydrides are succinic, glutaric, adipic, pimelic, suberic, azelaic, sebacic, nonandicarboxylic, decandicarboxylic, terephthalic, isophthalic, o-phthalic, tetrahydrophthalic, hexahydrophthalic or trimellitic acid and acid anhydrides, such as o-phthalic, trimellitic or succinic anhydride or any mixtures thereof with one another.

Examples of such suitable alcohols are ethanediol, di-, tri-, or tetraethylene glycol, 1,2-propanediol, di-, tri-, tetrapropylene glycol, 1,3-propanediol, 1,4-butanediol, 1,3-butanediol, 2,3-butanediol, 1,5-pentanediol, 1,6-hexanediol, 2,2-dimethyl-1,3-propanediol, 1,4-dihydroxycyclohexane, 1,4-dimethylolcyclohexane, 1,8-octanediol, 1,10-decanediol, 1,12-dodecanediol, trimethylolpropane, glycerol or any mixtures thereof with one another.

The polyester polyols may also be based on natural raw materials, such as castor oil. It is also possible for the polyester polyols to be based on homo- or copolymers of lactones, as can preferably be obtained by an addition reaction of lactones or lactone mixtures, such as butyrolactone, c-caprolactone and/or methyl-c-caprolactone, with hydroxy-functional compounds, such as polyhydric alcohols having an OH functionality ≧2, for example of the abovementioned type.

Such polyester polyols preferably have number average molar masses of 400 to 4000 g/mol, particularly preferably of 500 to 2000 g/mol. Their OH functionality is preferably 1.5 to 3.5, particularly preferably 1.8 to 3.0.

Suitable polycarbonate polyols are obtainable in a manner known per se by reacting organic carbonates or phosgene with diols or diol mixtures.

Suitable organic carbonates are dimethyl, diethyl and diphenyl carbonate.

Suitable diols or mixtures comprise the polyhydric alcohols mentioned per se in connection with the polyester segments and having an OH functionality ≧2, preferably 1,4-butanediol, 1,6-hexanediol and/or 3-methylpentanediol, or polyester polyols can be converted into polycarbonate polyols.

Such polycarbonate polyols preferably have number average molar masses of 400 to 4000 g/mol, particularly preferably of 500 to 2000 g/mol. The OH functionality of these polyols is preferably 1.8 to 3.2, particularly preferably 1.9 to 3.0.

Suitable polyether polyols are polyadducts of cyclic ethers with OH- or NH-functional initiator molecules, which polyadducts optionally have a block structure.

Suitable cyclic ethers are, for example, styrene oxides, ethylene oxide, propylene oxide, tetrahydrofuran, butylene oxide, epichlorohydrin and any desired mixtures thereof.

Initiators which may be used are the polyhydric alcohols mentioned in connection with the polyester polyols and having an OH functionality ≧2 and primary or secondary amines and amino alcohols.

Such polyether polyols preferably have number average molar masses of 250 to 10000 g/mol, particularly preferably of 500 to 8500 g/mol and very particularly preferably of 600 to 4500 g/mol. The OH functionality is preferably 1.5 to 4.0, particularly preferably 1.8 to 3.0.

In addition, aliphatic, araliphatic or cycloaliphatic di-, tri- or polyfunctional alcohols having a low molecular weight, i.e. having molecular weights of less than 500 g/mol, and having short chains, i.e. containing 2 to 20 carbon atoms, are also suitable as constituents of component e), as polyfunctional, isocyanate-reactive compounds.

These may be, for example, ethylene glycol, diethylene glycol, triethylene glycol, tetraethylene glycol, dipropylene glycol, tripropylene glycol, 1,2-propanediol, 1,3-propanediol, 1,4-butanediol, neopentylglycol, 2-ethyl-2-butylpropanediol, trimethylpentanediol, diethyloctanediol positional isomers, 1,3-butylene glycol, cyclohexanediol, 1,4-cyclohexanedimethanol, 1,6-hexanediol, 1,2- and 1,4-cyclohexanediol, hydrogenated bisphenol A (2,2-bis(4-hydroxycyclohexyl)propane), 2,2-dimethyl-3-hydroxypropionic acid (2,2-dimethyl-3-hydroxypropyl ester). Examples of suitable triols are trimethylolethane, trimethylolpropane or glycerol. Suitable higher functional alcohols are ditrimethylolpropane, pentaerythritol, dipentaerythriol or sorbitol.

One or more photoinitiators are used as component d). These are usually initiators which can be activated by actinic radiation and initiate a polymerization of the corresponding polymerizable groups. Photoinitiators are commercially sold compounds known per se, a distinction being made between monomolecular (type I) and bimolecular (type II) initiators. Furthermore, depending on the chemical nature, these initiators are used for free radical, anionic (or), cationic (or mixed) forms of the abovementioned polymerizations.

(Type I) systems for the radical photopolymerization are, for example, aromatic ketone compounds, e.g. benzophenones, in combination with tertiary amines, alkylbenzophenones, 4,4′-bis(dimethylamino)benzophenone (Michler's ketone), anthrone and halogenated benzophenones or mixtures of said types. Further suitable are (type II) initiators, such as benzoin and its derivatives, benzil ketals, acylphosphine oxides, e.g. 2,4,6-trimethylbenzoyldiphenylphosphine oxide, bisacyclophosphine oxide, phenylglyoxylic esters, camphorquinone, alpha-aminoalkylphenone, alpha,alpha-dialkoxyacetophenone, 1-[4-(phenylthio)phenyl]octane-1,2-dione 2-(O-benzoyloxime) and alpha-hydroxyalkylphenone. The photoinitiator systems described in EP-A 0223587 and consisting of a mixture of an ammonium arylborate and one or more dyes can also be used as a photoinitiator. For example, tetrabutylammonium triphenylhexylborate, tetrabutylammonium tris(3-fluorophenyl)hexylborate and tetrabutylammonium tris-(3-chloro-4-methylphenyl)hexylborate Ph₃B^{⊖}Bu, (Napht)₃B^{⊖}Bu are suitable as the ammonium arylborate. Suitable dyes are, for example, new methylene blue, thionine, basic yellow, pinacynol chloride, rhodamine 6G, gallocyanine, ethyl violet, Victoria blue R, Celestine blue, quinaldine red, crystal violet, brilliant green, astrazon orange G, darrow red, pyronine Y, basic red 29, pyrillium I, cyanine and methylene blue, azure A (Cunningham et al., RadTech98 North America UV/EB Conference Proceedings, Chicago, Apr. 19-22, 1998).

The photoinitiators used for the anionic polymerization are as a rule (type I) systems and are derived from transition metal complexes of the first row. Here, chromium salts, such as, for example, trans-Cr(NH₃)₂(NCS)₄⁻ (Katal et al, Macromolecules 1991, 24, 6872) or ferrocenyl compounds (Yamaguchi et al. Macromolecules 2000, 33, 1152) are known. A further possibility of anionic polymerization consists in the use of dyes, such as crystal violet leuconitrile or malachite green leuconitrile, which can polymerize cyanoacrylates by photolytic decomposition (Neckers et al. Macromolecules 2000, 33, 7761). However, the chromophore is incorporated into the polymer thereby so that the resulting polymers are coloured through.

The photoinitiators used for the cationic polymerization substantially comprise three classes: aryldiazonium salts, onium salts (here specifically: iodonium, sulphonium and selenonium salts) and organometallic compounds. Both in the presence and in the absence of a hydrogen donor, phenyldiazonium salts can, when irradiated, produce a cation that initiates the polymerization. The efficiency of the total system is determined by the nature of the counterions used for the diazonium compound. The not very reactive but very expensive SbF₆⁻. AsF₆⁻ or PF₆⁻ are preferred here. For use in coating thin films, these compounds are as a rule not very suitable since the surface quality is reduced via the nitrogen liberated after exposure (pinholes) (Li et al., Polymeric Materials Science and Engineering, 2001, 84, 139). Very widely used and also commercially available in a variety of forms are onium salts, especially sulphonium and iodonium salts. The photochemistry of these compounds has been investigated for a long time. After excitation, the iodonium salts initially decompose homolytically and thus produce a free radical and a radical cation which is stabilized by H abstraction, liberates a proton and then initiates the cationic polymerization (Dektar et al. J. Org. Chem. 1990, 55, 639; J. Org. Chem., 1991, 56. 1838). This mechanism permits the use of iodonium salts also for the radical photopolymerization. The choice of the counterion is once again very important here, and the very expensive SbF₆⁻, AsF₆⁻ or PF₆⁻ are likewise preferred. Otherwise, the substitution of the aromatic can be quite freely chosen in this structure class and said choice is determined substantially by the availability of suitable starting building blocks for synthesis. The sulphonium salts are compounds which decompose according to Norrish(II) (Crivello et al., Macromolecules, 2000, 33, 825). In the case of sulphonium salts, too, the choice of the counterion is of critical importance, which manifests itself substantially in the curing rate of the polymers. The best results are obtained as a rule with SbF₆⁻ salts. Since the self-absorption of iodonium and sulphonium salts is at <300 nm, these compounds must be appropriately sensitized for the photopolymerization with near UV or short-wave visible light. This is effected by the use of relatively highly absorbing aromatics, such as, for example, anthracene and derivatives (Gu et al., Am. Chem. Soc. Polymer Preprints, 2000, 41 (2), 1266) or phenothiazine or derivatives thereof (Hua et al, Macromolecules 2001, 34, 2488-2494).

It may also be advantageous to use mixtures of these compounds. Depending on the radiation source used for curing, type and concentration of photoinitiator must be adapted in a manner known to the person skilled in the art. The abovementioned adjustment with regard to the photopolymerization is easily possible for a person skilled in the art in the form of routine experiments within the below-mentioned quantity ranges of the components and the synthesis components available in each case for selection, in particular the preferred synthesis components.

Preferred photoinitiators d) are mixtures of tetrabutylammonium tetrahexylborate, tetrabutylammonium triphenylhexylborate, tetrabutylammonium tris(3-fluorophenyl)hexylborate and tetrabutylammonium tris(3-chloro-4-methylphenyl)hexylborate with dyes, such as, for example, astrazon orange G, methylene blue, new methylene blue, azure A, pyrillium I, safranine O, cyanine, gallocyanine, brilliant green, crystal violet, ethyl violet and thionine.

In addition to the components a) to d), free radical stabilizers, catalysts and further additives can be concomitantly used.

Suitable free radical stabilizers are inhibitors and antioxidants as described in “Methoden der organischen Chemie [Methods of Organic Chemistry]” (Houben-Weyl), 4th Edition, Volume XIV/1, page 433ff, Georg Thieme Verlag, Stuttgart 1961, Suitable classes of substances are, for example, phenols, such as for example 2,6-di-tert-butyl-4-methylphenol, cresols, hydroquinones, benzyl alcohols, such as, for example, benzhydrol, optionally also quinones, such as, for example, 2,5-di-tert-butylquinone, optionally also aromatic amines, such as diisopropylamine or phenothiazine. Preferred free radical stabilizers are 2,6-di-tert-butyl-4-methylphenol, phenothiazine and benzhydrol.

Furthermore, one or more catalysts may be used. These preferably catalyse the urethane formation. Amines and metal compounds of the metals tin, zinc, iron, bismuth, molybdenum, cobalt, calcium, magnesium and zirconium are preferably suitable for this purpose. Tin octanoate, zinc octanoate, dibutyltin dilaurate, dimethyltin dicarboxylate, iron(III) acetylacetonate, iron(II) chloride, zinc chloride, tetraalkylammonium hydroxides, alkali metal hydroxides, alkali metal alcoholates, alkali metal salts of long-chain fatty acids having 10 to 20 carbon atoms and optionally OH side groups, lead octanoate and tertiary amines, such as triethylamine, tributylamine, dimethylbenzylamine, dicyclohexylmethylamine, dimethylcyclohexylamine, tetramethyldiaminodiethyl ether, bis(dimethylaminopropyl)urea, N-methyl- or N-ethylmorpholine, N,N′-dimorpholinodiethyl ether (DMDEE), N-cyclohexylmorpholine, N,N,N′,N′-tetramethylethylenediamine, N,N,N′,N′-tetramethylbutanediamine, N,N,N′,N′-tetramethyl-1,6-hexanediamine, pentamethyldiethylenetriamine, dimethylpiperazine, N-dimethylaminoethylpiperidine, 1,2-dimethylimidazole, N-hydroxypropylimidazole, 1-azabicyclo[2,2,0]octane, 1,4-diazabicyclo[2.2.2]octane (Dabco) or alkanolamine compounds, such as triethanolamine, triisopropanolamine, N-methyl- and N-ethyldiethanolamine, dimethylaminoethanol, 2-(N,N-dimethylaminoethoxy)ethanol or N-tris-(dialkylaminoalkyl)hexahydrotriazines, e.g. N,N′,N-tris(dimethylaminopropyl)-s-hexahydrotriazine, diazabicyclononane, diazabicycloundecane, 1,1,3,3-tetramethylguanidine, 1,3,4,6,7,8-hexahydro-1-methyl-2H-pyrimido[1,2-a]pyrimidine are particularly preferred.

Particularly preferred catalysts are dibutyltin dilaurate, dimethyltin dicarboxylate, iron(III) acetylacetonate, 1,4-diazabicyclo[2.2.2]octane, diazabicyclononane, diazabicycloundecane, 1,1,3,3-tetramethylguanidine, 1,3,4,6,7,8-hexahydro-1-methyl-2H-pyrimido[1,2-a]-pyrimidine.

For example, solvents, plasticizers, levelling agents, wetting agents, antifoams or adhesion promoters, but also polyurethanes, thermoplastic polymers, oligomers, compounds having further functional groups, such as, for example, acetals, epoxide, oxetanes, oxazolines, dioxolanes and/or hydrophilic groups, such as, for example, salts and/or polyethylene oxides, may be present as further auxiliaries and additives.

Preferably used solvents are readily volatile solvents having good compatibility with the 2-component formulations according to the invention, for example ethyl acetate, butyl acetate and/or acetone.

Preferred used plasticizers are liquids having good dissolution properties, low volatility and a high boiling point. It may also be advantageous simultaneously to use additives of one type. Of course, it may also be advantageous to use a plurality of additives of a plurality of types.

The polyurethane compositions according to the invention preferably comprise

10 to 94.999% by weight of the unsaturated urethanes of the formulae (I) to (III) essential to the invention as component a)
5 to 89.999% by weight of components b) and e) or of the corresponding reaction products of b) with c),
0.001 to 10% by weight of photoinitiators d),
0 to 10% by weight of free radical stabilizers
0 to 4% by weight of catalysts
0 to 70% by weight of auxiliaries and additives.

The polyurethane compositions according to the invention particularly preferably comprise

15 to 70% by weight of the unsaturated urethanes of the formulae (I) to (III) essential to the invention as component a)
10 to 84.899% by weight of components b) and c) or the corresponding reaction products of b) with c),
0.1 to 7.5% by weight of photoinitiators d),
0.001 to 1% by weight of free radical stabilizers
0 to 3% by weight of catalysts
0 to 50% by weight of auxiliaries and additives.

The polyurethane compositions according to the invention particularly preferably comprise

20 to 50% by weight of the unsaturated urethanes of the formulae (I) to (III) essential to the invention as a)
25 to 79.489% by weight of components b) and c) or of the corresponding reaction products of b) with c),
0.5 to 5% by weight of photoinitiators d),
0.01 to 0.5% by weight of free radical stabilizers
0.001 to 2% by weight of catalysts
0 to 35% by weight of auxiliaries and additives.

The components b) and c) are used in an OH/NCO ratio to one another of typically from 0.5 to 2.0, preferably from 0.95 to 1.50, particularly preferably from 0.97 to 1.33.

The process according to the invention for the production of media for recording visual holograms is preferably carried out by a procedure in which the synthesis components of the polyurethane compositions according to the invention, with the exception of component b), are homogenously mixed with one another and component b) is admixed only immediately before application to the substrate or in the mould.

All methods and apparatuses known per se to the person skilled in the art from mixing technology, such as, for example, stirred tanks or both dynamic and static mixers, can be used for mixing. However, apparatuses without dead spaces or with only small dead spaces are preferred. Processes in which the mixing is effected within a very short time and with very vigorous thorough mixing of the two components to be mixed are furthermore preferred. In particular, dynamic mixers, in particular those in which the components come into contact with one another only in the mixer, are suitable for this purpose.

The temperatures are 0 to 100° C., preferably 10 to 80° C., particularly preferably 20 to 60° C., very particularly preferably 20 to 40° C.

If necessary, degassing of the individual components or of the total mixture under a reduced pressure of, for example, 1 mbar can also be carried out. Degassing, in particular after addition of component b), is preferred in order to prevent bubble formation by residual gases in the media obtainable.

Prior to admixing component b), the mixtures can be stored as storage-stable intermediate, optionally over several months.

After the admixing of component b) of the polyurethane compositions according to the invention, a clear, liquid formulation is obtained which, depending on composition, cures at room temperature within a few seconds to a few hours.

The ratio and the type and reactivity of the synthesis components of polyurethane compositions are preferably adjusted so that the curing begins within minutes to one hour after admixing of the component b) at room temperature. In a preferred embodiment, the curing is accelerated by heating the formulation, after the admixing, to temperatures between 30 and 180° C., preferably 40 to 120° C., particularly preferably 50 to 100° C.

The above mentioned approach with regard to the curing behaviour is possible for a person skilled in the art in the form of routine experiments within the above mentioned quantity range of the components and of the synthesis components available in each case for selection, in particular the preferred synthesis components.

Immediately after complete mixing of all components, the polyurethane compositions according to the invention have viscosities at 25° C. of typically 10 to 100000 mPa·s, preferably 100 to 20000 mPa·s, particularly preferably 200 to 15000 mPa·s, especially preferably 500 to 10000 mPa·s, so that they have very good processing properties even in solvent-free form. In solution with suitable solvents, viscosities at 25° C. of below 10000 mPa·s, preferably below 2000 mPa·s, particularly preferably below 500 mPa·s, can be established.

Polyurethane compositions of the abovementioned type which, in an amount of 15 g and with a catalyst content of 0.004% by weight, cure in less than 4 hours at 25° C. or, at a catalyst content of 0.02%, cure in less than 10 minutes at 25° C.

For application to a substrate or in a mould, all respective customary methods known to the person skilled in the art are suitable, such as, in particular, knife coating, casting, printing, screen printing, spraying or inkjet printing.

With the polyurethane compositions according to the invention, holograms for optical applications in the entire visible and near UV range (300-800 nm) can be produced by appropriate exposure processes. Visual holograms comprise all holograms which can be recorded by methods known to the person skilled in the art, including, inter alia, in-line (Gabor) holograms, off-axis holograms, full-aperture transfer holograms, white light transmission holograms (“rainbow holograms”), Denisyuk holograms, off-axis reflection holograms, edge-lit holograms and holographic stereograms; reflection holograms, Denisyuk holograms, transmission holograms are preferred. Optical elements, such as lenses, mirrors, deflection mirrors, filters, diffusion screens, diffraction elements, light guides, wave guides, projection screens and/or masks are preferred. Frequently, these optical elements show a frequency selectivity depending on how the holograms were exposed and which dimensions the hologram has.

In addition, it is also possible by means of the polyurethane compositions according to the invention to produce holographic images or displays, such as, for example, for personal portraits, biometric representations in security documents, or generally of images or image structures for advertising, security labels, trademark protection, trademark branding, labels, design elements, decorations, illustrations, multi-journey tickets, images and the like and images which can represent digital data, inter alia also in combination with the products described above. Holographic images may give the impression of a three-dimensional image but they can also represent image sequences, short films or a number of different objects, depending on the angle from which they are illuminated, the light source (including moving light source) which is used, etc. Owing to these varied design possibilities, holograms, in particular volume holograms, are an attractive technical solution for the abovementioned application.

The present invention therefore furthermore relates to the use of the media according to the invention for recording visual holograms and for producing optical elements, images, displays and to a method for recording holograms with the use of the media according to the invention.

All the references described above are incorporated by reference in its entirety for all useful purposes.

While there is shown and described certain specific structures embodying the invention, it will be manifest to those skilled in the art that various modifications and rearrangements of the parts may be made without departing from the spirit and scope of the underlying inventive concept and that the same is not limited to the particular forms herein shown and described.

### EXAMPLES

The following examples are mentioned for illustrating the photopolymers according to the invention but are not to be understood as being limiting. Unless noted otherwise, all percentage data are based on percent by weight.

### Example 1

0.1 g of 2,6-Di-tert-butyl-4-methylphenol, 0.05 g of dibutyltin dilaurate (Desmorapid Z, Bayer MaterialScience AG, Leverkusen, Germany) and 213.07 g of a 27% strength solution of tris(p-isocyanatophenyl)thiophosphate in ethyl acetate (Desmodur® RFE, product of Bayer MaterialScience AG, Leverkusen, Germany) were initially introduced into a 500 ml round-bottomed flask and heated to 60° C. Thereafter, 42.37 g of 2-hydroxyethyl acrylate were added dropwise and the mixture was kept further at 60° C. until the isocyanate content was below 0.1%. Thereafter, cooling was effected and the ethyl acetate was completely removed in vacuo. The product was obtained as a semicrystalline solid.

### Example 2

0.03 g of 2,6-di-tert-butyl-4-methylphenol, 0.05 g of dibutyltin dilaurate and 150.34 g of a 27% strength solution of tris(p-isocyanatophenyl) thiophosphate in ethyl acetate were initially introduced into a 250 ml round-bottomed flask and heated to 60° C. Thereafter, 14.95 g of 2-hydroxyethyl acrylate were added dropwise and the mixture was kept further at 60° C. until the isocyanate content was below 3.3%. Thereafter, 44.33 g of poly(ε-capro-lactone) monoacrylate (Tone M100, product of Dow Chemicals Inc.) were added dropwise and kept further at 60° C. until the isocyanate content had fallen below 0.1%. Thereafter, cooling was effected and ethyl acetate was completely removed in vacuo. The product was obtained as a viscous liquid.

### Example 3

0.1 g of 2,6-di-tert-butyl-4-methylphenol, 0.05 g of dibutyltin dilaurate and 189.52 g of a 27% strength solution of triphenylmethane 4,4′,4″-triisocyanate in ethyl acetate were initially introduced into a 500 ml round-bottomed flask and heated to 65° C. Thereafter, 48.68 g of 2-hydroxyethyl acrylate were added dropwise and the mixture was kept further at 65° C. until the isocyanate content was below 0.1%. Thereafter, cooling was effected and the ethyl acetate was completely removed in vacuo. The product was obtained as a semicrystalline solid.

### Example 4

0.06 g of 2,6-di-tert-butyl-4-methylphenol, 0.03 g of Desmorapid Z and 122.6 g of a 27% strength solution of tris(p-isocyanatophenyl) thiophosphate in ethyl acetate were initially introduced into a 500 ml round-bottomed flask and heated to 60° C. Thereafter, 27.3 g of hydroxypropyl acrylate were added dropwise and the mixture was kept further at 60° C. until the isocyanate content was below 0.1%. Thereafter, cooling was effected and the ethyl acetate was completely removed in vacuo. The product was obtained as a light yellow liquid.

### Example 5

0.06 g of 2,6-di-tert-butyl-4-methylphenol, 0.03 g of Desmorapid Z, 120.2 g of a 27% strength solution of tris(p-isocyanatophenyl) thiophosphate in ethyl acetate were initially introduced into a 500 ml round-bottomed flask and heated to 60° C. Thereafter, 29.7 g of 4-hydroxybutyl acrylate were added dropwise and the mixture was kept further at 60° C. until the isocyanate content was below 0.1%. Thereafter, cooling was effected and the ethyl acetate was completely removed in vacuo. The product was obtained as a light yellow liquid.

### Example 6

0.07 g of 2,6-di-tert-butyl-4-methylphenol, 0.04 g of Desmorapid Z, 109.1 g of a 27% strength solution of tris(p-isocyanatophenyl) thiophosphate in ethyl acetate were initially introduced into a 500 ml round-bottomed flask and heated to 60° C. Thereafter, 40.8 g of polyethylene glycol monomethacrylate (PEM3, from LAPORTE Performance Chemicals UK LTD) were added dropwise and the mixture was kept further at 60° C. until the isocyanate content was below 0.1%. Thereafter, cooling was effected and the ethyl acetate was completely removed in vacuo. The product was obtained as a light yellow liquid.

### Preparation of the Polyol Component:

0.18 g of tin octanoate, 374.81 g of c-caprolactone and 374.81 g of a difunctional polytetrahydrofuran polyether polyol (equivalent weight 500 g/mol OH) were additionally introduced into a 1 l flask and heated to 120° C. and kept at this temperature until the solids content (proportion of nonvolatile constituents) was 99.5% by weight or higher. Thereafter, cooling was effected and the product was obtained as a waxy solid.

### Comparative Medium 1:

7.61 g of the polyol component prepared as described above were mixed with 0.50 g of urethane acrylate from Example 1, 0.10 g of CGI 909 (CGI 909 is an experimental product sold in 2008 by Ciba Inc., Basel, Switzerland) and 0.01 g of new methylene blue, 0.35 g of N-ethylpyrrolidone and 0.02 g of 20 μm glass beads at 50° C. so that a clear solution was obtained. Thereafter, cooling to 30° C. was effected, 1.41 g of Desmodur® XP 2410 (experimental product of Bayer MaterialScience AG, Leverkusen, Germany, hexane diisocyanate-based polyisocyanate, proportion of iminooxadiazinedione at least 30%, NCO content: 23.5%) were added and mixing was effected again. Finally, 0.006 g of Fomrez UL 28 (urethanization catalyst, commercial product of Momentive Performance Chemicals, Wilton, Conn., USA) was added and mixing was effected again briefly. The liquid material obtained was then transferred to a glass plate and covered there with a second glass plate. This test specimen was cured for 12 hours under 15 kg weights at room temperature.

### Medium 1:

7.19 g of the polyol component prepared as described above were mixed with 1.00 g of urethane acrylate from Example 1, 0.10 g of CGI 909 and 0.01 g of new methylene blue, 0.35 g of N-ethylpyrrolidone and 0.02 g of 20 μm glass beads at 50° C. so that a clear solution was obtained. Thereafter, cooling to 30° C. was effected, 1.33 g of Desmodur® XP 2410 (experimental product of Bayer MaterialScience AG, Leverkusen, Germany, hexane diisocyanate-based polyisocyanate, proportion of iminooxadiazinedione at least 30%, NCO content: 23.5%) were added and mixing was effected again. Finally, 0.009 g of Fomrez UL 28 was added and mixing was effected again briefly. The liquid material obtained was then transferred to a glass plate and covered there with a second glass plate. This test specimen was cured for 12 hours under 15 kg weights at room temperature.

### Medium 2:

6.98 g of the polyol component prepared as described above were mixed with 1.25 g of urethane acrylate from Example 1, 0.10 g of CGI 909 and 0.01 g of new methylene blue, 0.35 g of N-ethylpyrrolidone and 0.02 g of 20 μm glass beads at 50° C. so that a clear solution was obtained. Thereafter, cooling to 30° C. was effected, 1.29 g of Desmodur® XP 2410 were added and mixing was effected again. Finally, 0.009 g of Fomrez UL 28 was added and mixing was effected again briefly. The liquid material obtained was then transferred to a glass plate and covered there with a second glass plate. This test specimen was cured for 12 hours under 15 kg weights at room temperature.

### Medium 3:

8.75 g of the polyol component prepared as described above were mixed with 3.75 g of urethane acrylate from Example 1, 0.15 g of CGI 909 and 0.015 g of new methylene blue, 0.52 g of N-ethylpyrrolidone and 0.02 g of 20 μm glass beads at 50° C. so that a clear solution was obtained. Thereafter, cooling to 30° C. was effected, 1.647 g of Desmodur® XP 2410 were added and mixing was effected again. Finally, 0.009 g of Fomrez UL 28 was added and mixing was effected again briefly. The liquid material obtained was then transferred to a glass plate and covered there with a second glass plate. This test specimen was cured for 12 hours under 15 kg weights at room temperature.

### Medium 4:

6.54 g of the polyol component prepared as described above were mixed with 1.77 g of urethane acrylate from Example 2, 0.10 g of CGI 909 and 0.01 g of new methylene blue, 0.35 g of N-ethylpyrrolidone and 0.015 g of 17 μm glass beads at 50° C. so that a clear solution was obtained. Thereafter, cooling to 30° C. was effected, 1.21 g of Desmodur® XP 2410 were added and mixing was effected again. Finally, 0.006 g of Fomrez UL 28 was added and mixing was effected again briefly. The liquid material obtained was then transferred to a glass plate and covered there with a second glass plate. This test specimen was cured for 12 hours under 15 kg weights at room temperature.

### Medium 5:

5.92 g of the polyol component prepared as described above were mixed with 2.50 g of urethane acrylate from Example 4, 0.10 g of CGI 909 and 0.01 g of new methylene blue, 0.35 g of N-ethylpyrrolidone and 0.015 g of 20 μm glass beads at 50° C. so that a clear solution was obtained. Thereafter, cooling to 30° C. was effected, 1.10 g of Desmodur® XP 2410 were added and mixing was effected again. Finally, 0.006 g of Fomrez UL 28 was added and mixing was effected again briefly. The liquid material obtained was then transferred to a glass plate and covered there with a second glass plate. This test specimen was cured for 12 hours under 15 kg weights at room temperature.

### Medium 6:

5.92 g of the polyol component prepared as described above were mixed with 2.50 g of urethane acrylate from Example 5, 0.10 g of CGI 909 and 0.01 g of new methylene blue, 0.35 g of N-ethylpyrrolidone and 0.015 g of 20 μm glass beads at 50° C. so that a clear solution was obtained. Thereafter, cooling to 30° C. was effected, 1.10 g of Desmodur® XP 2410 were added and mixing was effected again. Finally, 0.006 g of Fomrez UL 28 was added and mixing was effected again briefly. The liquid material obtained was then transferred to a glass plate and covered there with a second glass plate. This test specimen was cured for 12 hours under 15 kg weights at room temperature.

### Medium 7:

5.92 g of the polyol component prepared as described above were mixed with 2.50 g of urethane acrylate from Example 6, 0.10 g of CGI 909 and 0.01 g of new methylene blue, 0.35 g of N-ethylpyrrolidone and 0.015 g of 20 μm glass beads at 50° C. so that a clear solution was obtained. Thereafter, cooling to 30° C. was effected, 1.10 g of Desmodur® XP 2410 were added and mixing was effected again. Finally, 0.006 g of Fomrez UL 28 was added and mixing was effected again briefly. The liquid material obtained was then transferred to a glass plate and covered there with a second glass plate. This test specimen was cured for 12 hours under 15 kg weights at room temperature.

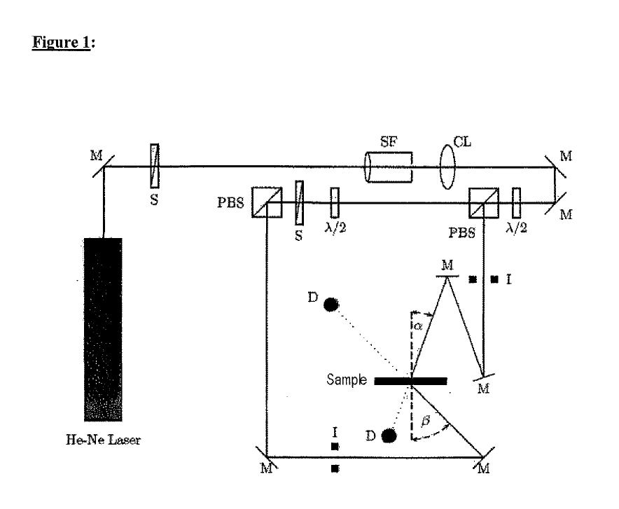

FIG. 1 shows the experimental holographic setup with which the diffraction efficiency (DE) of the media was measured. The media produced as described were then tested with regard to their holographic properties as follows:

The beam of an HeNe laser (emission wavelength 633 nm) was converted with the aid of the spatial filter (SF) and together with the collimation lens (CL) into a parallel homogenous beam. The final cross sections of the signal and reference beam are determined by the iris diaphragms (I). The diameter of the iris diaphragm opening is 4 mm. The polarization-dependent beam splitters (PBS) split the laser beam into two coherent equally polarized beams. By the λ/2 plates, the power of the reference beam was adjusted to 0.5 mW and the power of the signal beam to 0.65 mW. The powers were determined with the semiconductor detector (D) with the sample removed. The angle of incidence (α) of the reference beam is 21.8° and the angle of incidence (β) of the signal beam is 41.8°. At the location of the sample (medium), the interference field of the two overlapping beams produced a grating of light and dark strips which are perpendicular to the angle bisector of the two beams incident on the sample (reflection hologram). The strip spacing in the medium is ˜225 nm (refractive index of the medium assumed to be ˜1.49).

Holograms were written into the media in the following manner:

Both shutters (5) are opened for the exposure time t.

Thereafter, with the shutters (S) closed, the medium was allowed a time of 5 minutes for the diffusion of the still unpolymerized writing monomers.

The holograms written were now read in the following manner. The shutter of the signal beam remained closed. The shutter of the reference beam was opened. The iris diaphragm of the reference beam was closed to a diameter of <1 mm. This ensured that the beam was always completely in the previously written hologram for all angles of rotation (Ω) of the medium. Under computer control, the turntable now covered the angular range of Ω=0° to Ω=20° with an angle step width of 0.05°. At each angle Ω approached, the powers of the beam transmitted in the zeroth order were measured by means of the corresponding detector D and the powers of the beam diffracted in the first order were measured by means of the detector D. The diffraction efficiency was obtained at each angle Ω approached as the quotient of:

power in the detector of the diffracted beam/(power in the detector of the diffracted beam+power in the detector of the transmitted beam)

The maximum diffraction efficiency (DE) of the hologram, i.e. its peak value, was determined. It might have been necessary to change the position of the detector of the diffracted beam in order to determine this maximum value.

For one formulation, this procedure was repeated possibly several times for different exposure times t on different media in order to determine the mean energy dose of the incident laser beam during writing of the hologram at which DE reaches the saturation value. The mean energy dose E is obtained as follows:

E(mJ/cm²)=2·[(0.50 mW+0.67 mW)·t(s)]/[π·0.4² cm²]

The following measured values were obtained for DE at the dose E:

| | | Content of | | |
|---|---|---|---|---|
| | | urethane | | |
| | Urethane | acrylate in % | Dose | DE |
| Example | acrylate | by weight | (mJ/cm²) | [%] |
| Comparative medium | Example 1 | 5 | 4.56 | 11 |
| Medium 1 | Example 1 | 10 | 4.56 | 52 |
| Medium 2 | Example 1 | 12.5 | 4.56 | 57 |
| Medium 3 | Example 1 | 25 | 4.56 | 88 |
| Medium 4 | Example 2 | 17.7 | 12.5 | 77 |
| Medium 5 | Example 4 | 25 | 4.56 | 69 |
| Medium 6 | Example 5 | 25 | 4.56 | 85 |
| Medium 7 | Example 6 | 25 | 4.56 | 60 |

The diffraction efficiency DE obtained for the holographic media in the experiment described above should expediently be greater than 50% since then at least half the incident light is diffracted. This leads, in the total visible range, to useable, light and high-contrast holograms in the context of the above description.

The values found for the diffraction efficiency DE and the necessary dose show that the photopolymers based on the urethane acrylates according to the invention, in which the urethane acrylate content is greater than or equal to 10% by weight, are very suitable as holographic media in the context of the above description. Particularly good holographic media can be obtained if the content of the urethane acrylate is greater than or equal to 15% by weight.

1. A polyurethane composition comprising a writing monomer component a) containing at least 10% by weight, based on the total weight of said polyurethane composition, of one or more unsaturated urethanes a) of formulae (I), (II), and (III) as writing monomers and polymeric compounds or corresponding matrix precursors as a matrix for the writing monomers 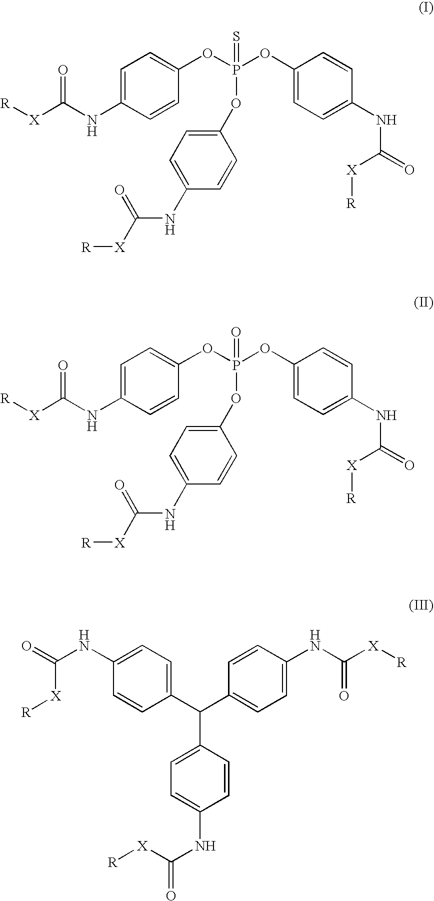
wherein
R is in each case, independently of one another, a radiation-curable group; and
X is in each case, independently of one another, a single bond between R and C═O or a linear, branched, or cyclic hydrocarbon radical which optionally contains heteroatoms and/or is optionally substituted by functional groups.

2. The polyurethane composition of claim 1, wherein R is a vinyl ether, acrylate, or methacrylate group.

3. The polyurethane composition of claim 1, wherein X is in each case a linear or branched oxyalkylene or polyoxyalkylene group.

4. The polyurethane composition of claim 1, wherein said one or more unsaturated urethanes a) are present in an amount of from 20 to 50% by weight, based on the total weight of said polyurethane composition.

5. The polyurethane composition of claim 1, wherein said corresponding matrix precursors comprise
an isocyanate component b);
an isocyanate-reactive component c); and
one or more photoinitiators d).

6. A process for producing media suitable for recording visual holograms comprising (1) applying the polyurethane composition of claim 1 to a substrate or in a mould and (2) curing said polyurethane composition.

7. A process for producing media suitable for recording visual holograms comprising (1) providing a mixture of the components of the polyurethane composition of claim 5, (2) applying said polyurethane composition to a substrate or in a mould and (3) curing said polyurethane composition, wherein component b) is admixed only finally immediately before the application in (2).

8. A medium suitable for recording visual holograms produced by the process of claim 6.

9. A method for recording holograms comprising exposing the medium of claim 8 by means of a laser beam.

10. An unsaturated urethane of formula (II) 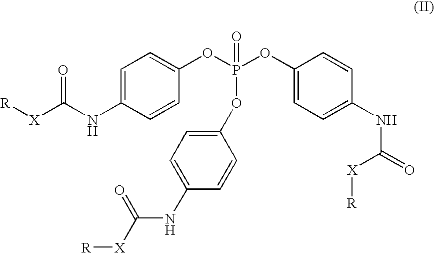
wherein
R is in each case, independently of one another, a radiation-curable group; and
X is in each case, independently of one another, a single bond between R and C═O or a linear, branched or cyclic hydrocarbon radical which optionally contains heteroatoms and/or is optionally substituted by functional groups.
